(19) United States
(12) Patent Application Publication
(10) Pub. No.: US 2020/0409442 A1
(43) Pub. Date: Dec. 31, 2020

(54) POWER SUPPLY CIRCUIT AND POWER SUPPLY VOLTAGE SUPPLY METHOD

(71) Applicant: ROHM CO., LTD., Kyoto-shi (JP)

(72) Inventors: Akira URYU, Kyoto-shi (JP); Osamu YANAGIDA, Kyoto-shi (JP); Tadayuki SAKAMOTO, Kyoto-shi (JP)

(21) Appl. No.: 16/912,216

(22) Filed: Jun. 25, 2020

(30) Foreign Application Priority Data
Jun. 25, 2019 (JP) 2019-117722

(51) Int. Cl. G06F 1/30; G06F 1/28; H02M 3/158; G06F 1/3206; G01R 19/165; G05F 1/46; H02J 9/00

(52) U.S. Cl. CPC G06F 1/30; G06F 1/28; H02M 3/1582; H02J 9/005; G01R 19/16528; G05F 1/465; G06F 1/3206

(57) ABSTRACT

In a normal state in which a main power supply supplies an input voltage having a first level, a step-down converter is enabled. In this state, the step-down converter steps down the input voltage and supplies a power supply voltage having a second level to a load. In the normal state, a step-up converter is operated in a forward direction. In this state, the step-up converter steps up the power supply voltage so as to charge a backup capacitor using a voltage having a third level. In a power supply disconnection state in which a disconnection of the input voltage occurs, the step-up converter is operated in a reverse direction. In this state, the step-up converter steps down a capacitor voltage across the backup capacitor, and supplies the power supply voltage having the second voltage level to the load.

### BACKGROUND

### Cross Reference to Related Applications

The present invention claims priority under 35 U.S.C. § 119 to Japanese Application No. 2019-117722 filed Jun. 25, 2019, the entire content of which is incorporated herein by reference.

### 1. FIELD

The present disclosure relates to a power supply circuit.

### 2. DESCRIPTION OF THE RELATED ART

A stable supply of power supply voltage is indispensable for an electronic component. In a storage apparatus such as a solid-state drive, hard disk, or the like, if a temporary disconnection of the power supply voltage occurs, it has the potential to cause destruction or loss of data during a storage operation. Accordingly, even if disconnection of the input voltage occurs, such an arrangement is required to maintain the power supply voltage over a period in which a load executes required protection processing such as data comparison. Such a function is referred to as power supply disconnection protection, “PLP” (Power Loss Protection), “PLI” (Power Loss Imminent), “PFP” (Power Failure protection), or the like.

FIG. 1 is a block diagram showing a system including a PLP function. A system 2 includes a main power supply 10, a load 20, and a power supply circuit 30. The main power supply 10 generates an input voltage V_{IN} on the order of 12 V. The load 20 includes a PMIC (power supply management circuit) 22, and multiple electronic components 24_1 through 24_n. The PMIC 22 receives a power supply voltage V_{DD} of 12 V. The PMIC 22 steps up or steps down the voltage, and supplies the stepped up or stepped down voltage to the electronic components 24_1 through 24_n.

The power supply circuit 30 is provided to the main power supply 10 and the load 20. The power supply circuit 30 includes a switch 32, a backup capacitor 34, and a step-up converter 36.

The switch 32 is provided on a power supply line 38 that couples the main power supply 10 and the load 20. During a period in which an effective input voltage V_{IN} is supplied, the switch 32 is turned on, and the input voltage V_{IN} is supplied to the load 20 as the power supply voltage V_{DD}. An input terminal IN of the step-up converter 36 is coupled to the power supply line 38. An output terminal OUT of the step-up converter 36 is coupled to the backup capacitor 34. During a period in which the input voltage V_{IN} is supplied, the step-up converter 36 steps up the input voltage V_{IN}, and charges the backup capacitor 34. With the capacitance of the backup capacitor 34 as C, and the voltage across the backup capacitor 34 as V_{storage}, the charge Q and the energy E stored in the backup capacitor 34 are represented by the following Expressions.

Q=C·V_{storage}

E=C·(V_{storage})²/2

When disconnection (loss) of the input voltage V_{IN} is detected, the power supply circuit 30 turns off the switch 32. Subsequently, the step-up converter 36 operates in a reverse mode in which the OUT side is switched to the input thereof and the IN side is switched to the output thereof. In this mode, the capacitor voltage V_{storage} across the backup capacitor 34 is stepped down to a voltage level of the power supply voltage V_{DD}, and the voltage thus stepped down is supplied to the load 20.

### SUMMARY

An embodiment of the present disclosure relates to a power supply circuit.

The power supply circuit comprises a step-down converter and a step-up converter. The step-down converter has an input terminal structured to be coupled to receive an input voltage from an external power supply, and is structured to be enabled in a normal state in which the input voltage has a first level, and to step down the input voltage and to supply a power supply voltage having a second level to an output terminal that is structured to be coupled to a load. The step-up converter is structured to operate in a forward direction so as to step up the power supply voltage, and to charge a backup capacitor using a voltage having a third level in the normal state, and is structured to operate in a reverse direction so as to step down a capacitor voltage across the backup capacitor, and to supply the power supply voltage having the second level to the load in a power supply disconnection state in which a disconnection of the input voltage occurs.

It is to be noted that any arbitrary combination or rearrangement of the above-described structural components and so forth is effective as and encompassed by the present embodiments. Moreover, all of the features described in this summary are not necessarily required by embodiments so that the embodiment may also be a sub-combination of these described features. In addition, embodiments may have other features not described above.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram showing a system having a PLP function;

FIG. 2 is a block diagram showing a system including a power supply circuit according to an embodiment 1;

FIG. 3 is a diagram for explaining the operation of the system shown in FIG. 2;

FIG. 4 is a diagram showing a specific example configuration of the power supply circuit shown in FIG. 2;

FIG. 5 is a block diagram showing a system including a power supply circuit according to an embodiment 2;

FIG. 6 is a diagram for explaining the operation of the system shown in FIG. 5;

FIG. 7 is a diagram showing a specific example configuration of the power supply circuit shown in FIG. 5;

FIG. 8 is a circuit diagram showing an example configuration of a converter controller;

FIG. 9A and FIG. 9B are operation waveform diagrams each showing the operation of the converter controller;

FIG. 10 is a block diagram showing a system including a power supply circuit according to an embodiment 3;

FIG. 11 is a diagram for explaining the operation of the system;

FIG. 12 is a diagram showing a specific example configuration of the power supply circuit; and

FIG. 13 is a block diagram showing a data storage apparatus having a PLP function.

### DETAILED DESCRIPTION

Embodiments of the present disclosure will be described more fully hereinafter with reference to the accompanying drawings in which like numerals represent like elements throughout the several figures, and in which example embodiments are shown. Embodiments of the claims may, however, be embodied in many different forms and should not be construed as limited to the embodiments set forth herein. The examples set forth herein are non-limiting examples and are merely examples among other possible examples.

In the present specification, a state represented by the phrase “the member A is coupled to the member B” includes a state in which the member A is indirectly coupled to the member B via another member that does not affect the electric connection between them, or that does not damage the functions of the connection between them, in addition to a state in which they are physically and directly coupled. Similarly, a state represented by the phrase “the member C is provided between the member A and the member B” includes a state in which the member A is indirectly coupled to the member C, or the member B is indirectly coupled to the member C via another member that does not affect the electric connection between them, or that does not damage the functions of the connection between them, in addition to a state in which they are directly coupled.

### Outline

An outline of several example embodiments of the disclosure follows. This outline is provided for the convenience of the reader to provide a basic understanding of such embodiments and does not wholly define the breadth of the disclosure. This outline is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later.

In one embodiment, the power supply circuit comprises: a step-down converter structured such that, in a normal state in which an input voltage having a first level is supplied from an external power supply, the step-down converter is enabled so as to step down the input voltage and to supply a power supply voltage having a second level to a load; and a step-up converter structured such that, in the normal state, the step-up converter operates in a forward direction so as to step up the power supply voltage, and to charge a backup capacitor using a voltage having a third level, and such that, in a power supply disconnection state in which a disconnection of the input voltage occurs, the step-up converter operates in a reverse direction so as to step down a capacitor voltage across the backup capacitor, and to supply the power supply voltage having the second level to the load.

Another embodiment of the present invention also relates to a power supply circuit. The power supply circuit comprises: a step-down converter having an input terminal and an output terminal, structured to receive an input voltage having a first level from an external power supply via the input terminal, to step down the input voltage, and to supply a power supply voltage having a second level to a load coupled to the output terminal; and a step-up converter structured to step up the power supply voltage, and to charge a backup capacitor using a voltage having a third level. When a disconnection of the input voltage occurs, a capacitor voltage across the backup capacitor is supplied to the input terminal of the step-down converter.

Yet another embodiment of the present invention relates to a power supply disconnection protection controller. The power supply disconnection protection controller is employed together with a switch, a step-down converter, and a step-up converter, so as to be structured as a power supply circuit. The power supply disconnection protection controller comprises: a judgement unit structured to monitor an input voltage received from an external power supply, and to judge whether the input voltage is in a normal state or a power supply disconnection state; a controller of the step-up converter; a switch controller structured (i) to turn on the switch in the normal state, and (ii) to turn off the switch in the power supply disconnection state; and a logic circuit structured such that (i) in the normal state, the step-down converter is enabled and the step-up converter is operated in a forward direction, and (ii) in the power supply disconnection state, the step-down converter is disabled and the step-up converter is operated in a reverse direction.

Yet another embodiment of the present invention also relates to a power supply disconnection protection controller. The power supply disconnection protection controller is employed together with a first switch, a second switch, a step-down converter, and a step-up converter, so as to be structured as a power supply circuit. The power supply disconnection protection controller comprises: a judgement unit structured to monitor an input voltage received from an external power supply, and to judge whether the input voltage is in a normal state or a power supply disconnection state; a controller of the step-down converter; a controller of the step-up converter; a switch controller structured (i) to turn on the first switch and to turn off the second switch in the normal state, and (ii) to turn off the first switch and to turn on the second switch in the power supply disconnection state; and a logic circuit structured (i) to enable the step-down converter and the step-up converter in the normal state, and (ii) to disable the step-down converter and the step-up converter in the power supply disconnection state.

### Embodiment 1

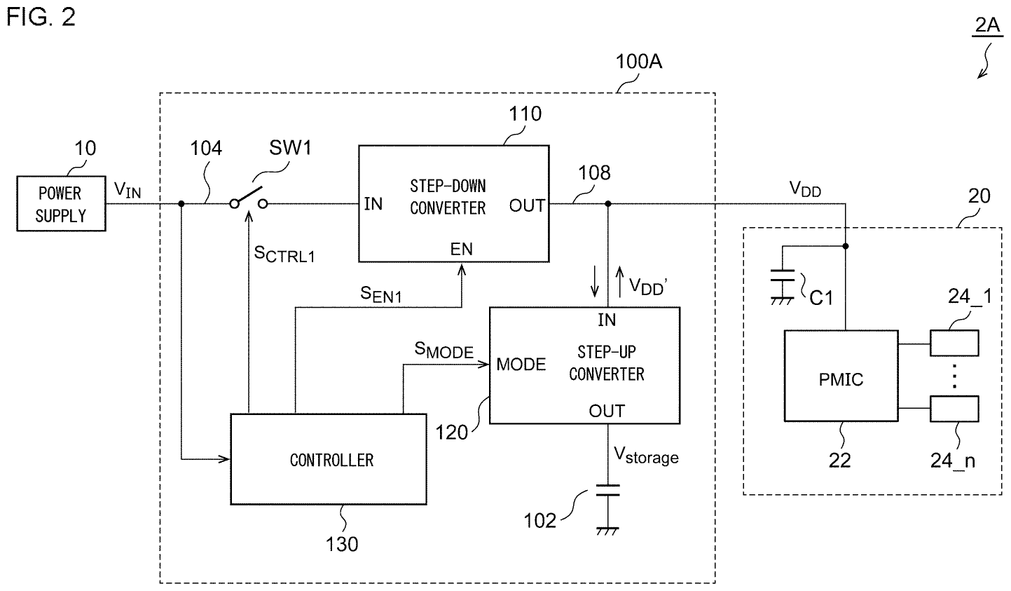

FIG. 2 is a block diagram showing a system 2A including a power supply circuit 100A according to an embodiment 1. The system 2A includes a main power supply 10, a load 20, and a power supply circuit 100A. The main power supply 10 is configured as an AC/DC converter or a USB (Universal Serial Bus). The main power supply 10 supplies a DC input voltage V_{IN} on the order of a first voltage level (12 V in the following description) to the power supply circuit 100A.

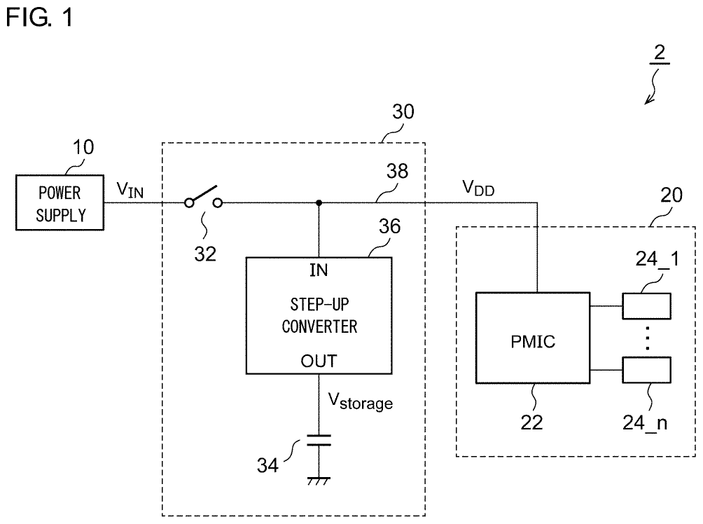

The load 20 includes a PMIC 22 and multiple electronic components 24_1 through 24_n. With the system 2 shown in FIG. 1, the PMIC 22 is configured as a component with an input of 12 V (i.e., a component employing the same input voltage level as the input voltage). In contrast, with the system 2A shown in FIG. 2, the PMIC 22 is configured with an input voltage having a second voltage level (e.g., in a range of 3 to 6 V; 5V is employed in the following description) that is lower than the first voltage level (12 V).

The power supply circuit 100A receives the input voltage V_{IN} of the first voltage level (12 V), and supplies the power supply voltage V_{DD} having a second voltage level (5 V) that is lower than the first voltage level to the load 20.

The power supply circuit 100A includes a switch SW1, a backup capacitor 102, a step-down converter 110, a step-up converter 120, and a controller 130. The controller 130 integrally controls the power supply circuit 100A. The switch SW1 is provided on an input line 104 extending from the main power supply 10 to the input IN of the step-down converter 110. The input voltage V_{IN} is supplied to the input terminal IN of the step-down converter 110 via the switch SW1. The output OUT of the step-down converter 110 is coupled to the load 20 via an output line 108. The step-down converter 110 is switchable between an enabled state and a disabled state. When the step-down converter 110 is set to the enabled state by the controller 130, the step-down converter 110 steps down the input voltage V_{IN}, and outputs, via its output OUT, the power supply voltage V_{DD} stabilized to the second voltage level. The power supply voltage V_{DD} is supplied to the load 20 via the output line 108.

The step-up converter 120 is arranged such that its input IN is coupled to the output line 108, and its output OUT is coupled to the backup capacitor 102. The step-up converter 120 is capable of switching the power transmission direction according to a mode control operation of the controller 130. In a first mode (step-up mode), the step-up converter 120 operates in a forward direction. In the first mode, the step-up converter 120 steps up the voltage V_{DD} at the input IN, and charges the backup capacitor 102 such that the voltage across the backup capacitor 102 becomes a third voltage level (30 V in the following description) that is higher than the first voltage level (12 V) and the second voltage level (5 V). With this, electric power is stored in the backup capacitor 102. The backup capacitor 102 functions as a power supply that operates when the power supply is lost.

In a second mode (step-down) mode, the relation between the input and the output of the step-up converter 120 is switched. In the second mode, the backup capacitor 102 functions as a power supply for the step-up converter 120. The step-up converter 120 operates in a reverse direction. In this state, the step-up converter 120 steps down the capacitor voltage V_{storage}, and generates, at the output line 108, a power supply voltage V_{DD′} stabilized to the second voltage level.

The controller 130 monitors the input voltage V_{IN} so as to judge whether the input voltage V_{IN} is in the normal state in which an effective input voltage V_{IN} is supplied or a power supply loss state in which the input voltage V_{IN} is disconnected. In the normal state, the controller 130 asserts the control signal S_{CTRL1} so as to turn on the switch SW1. Furthermore, the controller 130 asserts the control signal S_{EN1} so as to set the step-down converter 110 to the enabled state. Moreover, the step-up converter 120 is set to the first mode (step-up mode) by a control signal S_{MODE}.

In the power supply loss state, the controller 130 negates the control signal S_{CTRL1} so as to turn off the switch SW1. Furthermore, the controller 130 negates (deasserts) the control signal S_{EN1} so as to disable the step-down converter 110. Moreover, the step-up converter 120 is set to the second mode (step-down mode) by the control signal S_{MODE}.

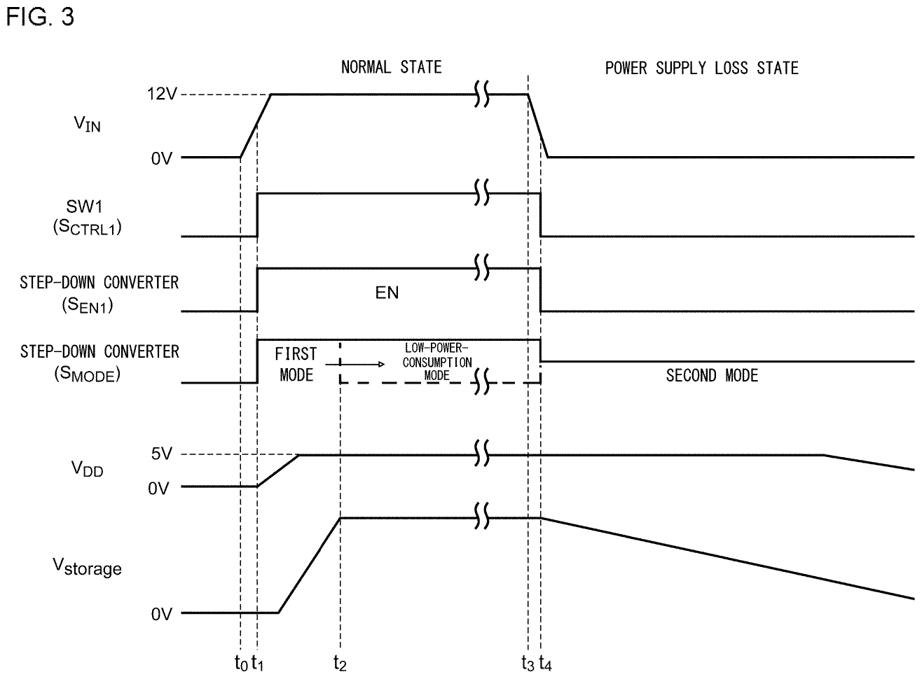

The above is the configuration of the system 2A. Next, description will be made regarding the operation thereof. FIG. 3 is a diagram for explaining the operation of the system 2A shown in FIG. 2. At the time point t₀, the system is started up, and the input voltage V_{IN} is supplied. When an effective input voltage V_{IN} is detected at the time point t₁, the controller 130 asserts the control signal S_{CTRL1} and the control signal S_{EN1}, so as to turn on the switch SW1 and enable the step-down converter 110. With this, the input voltage V_{IN} is stepped down, which generates the power supply voltage V_{DD} of 5 V at the output line 108. The power supply voltage V_{DD} thus generated is supplied to the load 20.

Furthermore, the controller 130 generates the control signal S_{MODE} so as to set the step-up converter 120 to the first mode. In this state, the backup capacitor 102 is charged, thereby raising the capacitor voltage V_{storage}. At the time point t₂, the capacitor voltage V_{storage} reaches the third voltage level (30 V). Subsequently, the capacitor voltage V_{storage} is maintained at a constant voltage level. After the time point t₂, the step-up converter 120 is set to a low-power-consumption mode. In this mode, the voltage across the backup capacitor 102 is maintained at a constant level. It should be noted that, in a case in which leak current of the backup capacitor 102 is negligible, after the time point t₂, the operation of the step-up converter may be suspended.

At the time point t₃, the input voltage V_{IN} is lost. When the controller 130 detects a power supply loss state at the time point t₄, the controller 130 negates the control signals S_{CTRL1} and S_{EN1}, which turns off the switch SW1, and sets the step-down converter 110 to the disabled state.

Furthermore, the controller 130 generates the control signal S_{MODE} so as to set the step-up converter 120 to the second mode. In this mode, the step-up converter 120 continuously maintains the voltage V_{DD} at the output line 108 at a constant level using the backup capacitor 102 as a power supply. The capacitor voltage V_{storage} falls with time. When the capacitor voltage V_{storage} becomes lower than 5 V, the power supply voltage V_{DD} also starts to fall.

The above is the operation of the system 2A. Next, description will be made regarding the advantages of the system 2A.

### First Advantage

With the system 2A, the voltage level of the power supply voltage V_{DD} to be supplied to the load 20 is changed to a voltage level that is lower than the input voltage V_{IN}. This allows the breakdown voltage of a smoothing capacitor C1 coupled to the input of the load 20 to be reduced. That is to say, the system 2 shown in FIG. 1 requires the capacitor C1 to be configured as a component having a breakdown voltage that is higher than 12 V. In contrast, with the system 2A shown in FIG. 2, it is sufficient for the capacitor C1 to have a breakdown voltage that is higher than 5 V. For example, the capacitor C1 may be preferably configured as a component having a breakdown voltage of 6.3 V. This allows the cost of the capacitor C1 to be reduced. Furthermore, low-breakdown-voltage capacitors have a large supply, and support a large number of options. Thus, from the viewpoint of stable supply of the system 2, the system 2A is advantageous.

### Second Advantage

In the system 2 shown in FIG. 1, the input IN of the step-up converter 36 is coupled to the power supply line 38 set to the same voltage level (12 V) as the input voltage V_{IN}. In this case, when the power supply is disconnected, the step-up converter 36 is capable of maintaining the output of the voltage level 12 V required by the load 20 before the capacitor voltage V_{storage} across the backup capacitor 34 falls to 12 V.

In contrast, in the system 2A shown in FIG. 2, the input IN of the step-up converter 120 is coupled to the output line 108 set to a voltage level (5 V) that is lower than the input voltage V_{IN}. With this, when the power supply is disconnected, the step-up converter 120 is capable of maintaining the output of the voltage level of 5 V required by the load 20 before the capacitor voltage V_{storage} falls to 5V. That is to say, such an arrangement allows the operating time of the load 20 to be increased after the power supply is lost.

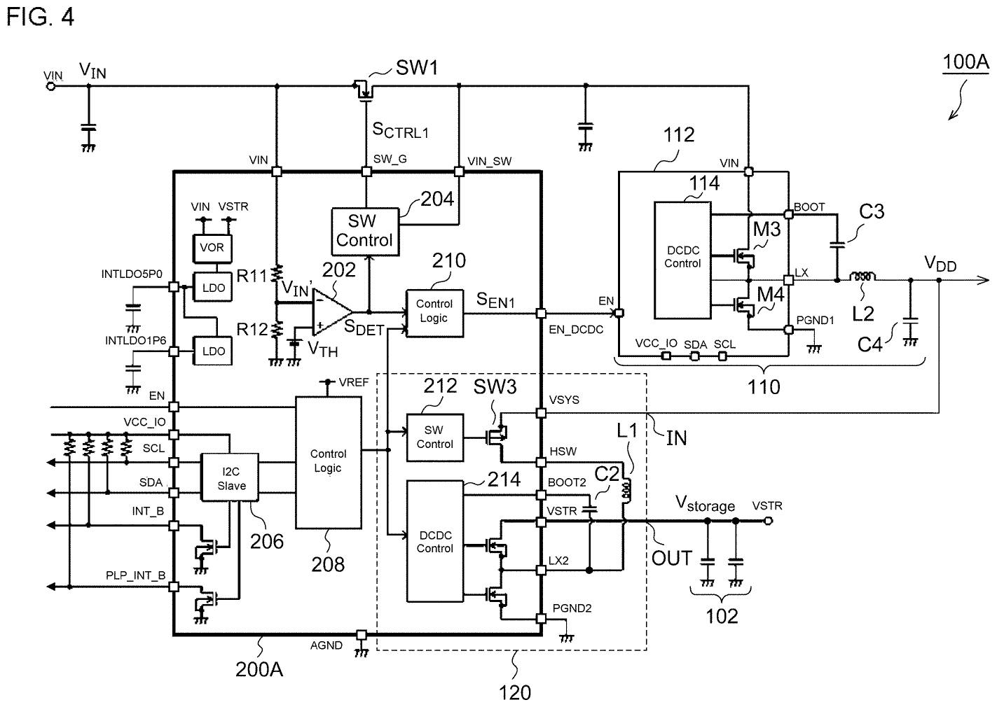

FIG. 4 is a diagram showing a specific example configuration of the power supply circuit 100A shown in FIG. 2. The power supply circuit 100A includes a PLP controller 200A. The PLP controller 200A is configured as a function IC on which the controller 130 and a part of the step-up converter 120 shown in FIG. 2 are integrated.

The input voltage V_{IN} is supplied to a VIN pin of the PLP controller 200A. The input voltage V_{IN} is divided by resistors R11 and R12. A comparator 202 is configured as a judgment unit that compares the input voltage V_{IN′} thus divided with a threshold voltage V_{TH}, and generates a detection signal S_{DET} that indicates a comparison result. When V_{IN′}>V_{TH}, the detection signal S_{DET} is set to the low level, which indicates a normal state. Conversely, when V_{IN′} <V_{TH}, the detection signal S_{DET} is set to the high level, which indicates a power supply loss state.

The switch SW1 is configured as an NMOS transistor. The gate of the switch SW1 is coupled to a switch gate (SW_G) pin of the PLP controller 200A. The switch controller 204 receives the detection signal S_{DET}. In the normal state, the switch controller 204 turns on the switch SW1. In the power supply loss state, the switch controller 204 turns off the switch SW1. It should be noted that the switch SW1 may be integrated on the PLP controller 200A. It should be noted that the switch SW1 may be configured as a PMOS transistor.

The PLP controller 200A is coupled to an unshown host controller. An enable (EN) pin, serial interface pins VCC_IO, SCL and SDA, interrupt pins INT_B and PLP_INT_B, and an interface circuit 206 are provided so as to support communication with the host controller.

A control logic 208 controls the operation of each block of the PLP controller 200A according to a control command received from the host controller. A control logic 210 generates an enable signal S_{EN1} for the step-down converter 110 according to the detection signal S_{DET} and a control signal received from the control logic 208.

The step-up converter 120 includes a switch SW3, a switching transistor M1, a synchronous rectification transistor M2, an inductor L1, a bootstrap capacitor C2, a switching controller 212, and a converter controller 214.

In the normal state, the switching controller 212 turns on the switch SW3. In the normal state, the converter controller 214 is set to the first mode. In this state, the switching operations of the transistors M1 and M2 are feedback controlled such that the capacitor voltage V_{storage} approaches a target level (30 V). After the capacitor voltage V_{storage} reaches the target level, the converter controller 214 is set to the low-power-consumption mode. In this mode, the capacitor voltage V_{storage} is maintained at the target level. In a case in which leak current from the capacitor is negligible, after the capacitor voltage V_{storage} reaches the target level, the switching controller 212 may turn off the switch SW3, so as to suspend the operation of the converter controller 214.

The step-down converter 110 includes a converter control IC 112, an inductor L2, a bootstrap capacitor C3, and an output capacitor C4. The control IC 112 includes transistors M3 and M4 and a converter controller 114. When the control signal S_{EN} input to the enable pin EN is asserted, the converter controller 114 is activated, and feedback controls the transistors M3 and M4 such that the power supply voltage V_{DD} approaches a target level (5 V).

The above is an example configuration of the power supply circuit 100A. Next, description will be made regarding a modification thereof. In FIG. 4, the converter controller 114 may be integrated on the PLP controller 200A. Also, the switch SW1 may be integrated on the PLP controller 200A.

The transistors M2 and M3 may each be configured as a PMOS transistor. In this case, the bootstrap capacitor may be omitted. The transistors M1 through M4 may each be configured as a discrete element.

### Embodiment 2

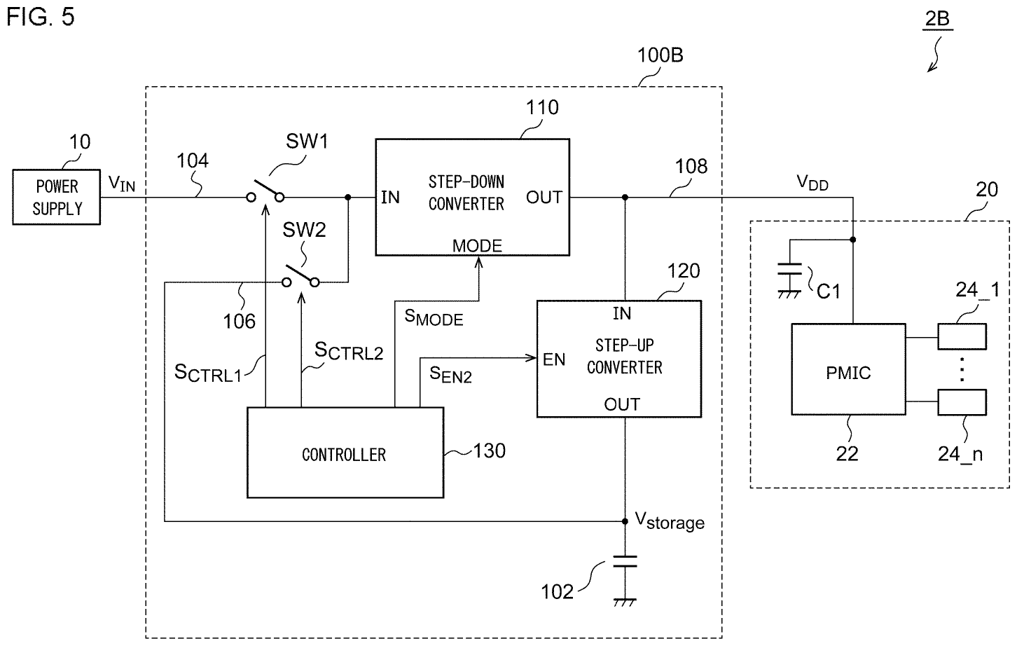

FIG. 5 is a block diagram showing a system 2B including a power supply circuit 100B according to an embodiment 2. The system 2B includes a main power supply 10, a load 20, and the power supply circuit 100B. The main power supply 10 and the load 20 have the same configurations as those shown in FIG. 2 (embodiment 1).

The power supply circuit 100B receives an input voltage V_{IN} with a first voltage level (12 V), and supplies, to the load 20, a power supply voltage V_{DD} having a second voltage level (5 V) that is lower than the first voltage level.

The power supply circuit 100B includes switches SW1 and SW2, a backup capacitor 102, a step-down converter 110, a step-up converter 120, and a controller 130. The controller 130 integrally controls the power supply circuit 100B.

The switch SW1 is arranged on the input line 104 extending from the main power supply 10 to an input IN of the step-down converter 110. The input voltage V_{IN} is supplied to the input terminal IN of the step-down converter 110 via the switch SW1. The output OUT of the step-down converter 110 is coupled to the load 20 via the output line 108.

The step-down converter 110 steps down the voltage at the input terminal IN, and outputs, via its output OUT, the power supply voltage V_{DD} stabilized to the second voltage level. The power supply voltage V_{DD} is supplied to the load 20 via the output line 108.

The step-up converter 120 is arranged such that its input IN is coupled to the output line 108 and its output OUT is coupled to the backup capacitor 102. The step-up converter 120 is switchable between the enabled state and the disabled state. When the controller 130 sets the step-up converter 120 to the enabled state, the step-up converter 120 steps up the voltage V_{DD} at the input IN so as to charge the backup capacitor 102 such that the voltage across the backup capacitor 102 becomes the third voltage level (30 V in the following description), which is higher than the first voltage level (12 V) and the second voltage level (5 V). With this, electric power is stored in the backup capacitor 102. The backup capacitor 102 functions as a power supply when the power supply is lost.

The power supply circuit 100B is configured such that the capacitor voltage V_{storage} is supplied to the input IN of the step-down converter 110 when a disconnection of the input voltage V_{IN} occurs. Specifically, the power supply circuit 100B includes a switch SW2 arranged on a backup line 106 extending from the backup capacitor 102 up to the input IN of the step-down converter 110. In a state in which the switch SW1 is turned off and the switch SW2 is turned on, the capacitor voltage V_{storage} functions as the input voltage of the step-down converter 110.

The controller 130 monitors the input voltage V_{IN} so as to judge whether it is in the normal state or a power supply loss state. In the normal state, the controller 130 asserts the control signal S_{CTRL1} and negates the control signal S_{CTRL2}, so as to turn on the switch SW1 and turn off the switch SW2. The step-down converter 110 steps down the input voltage V_{IN} supplied to the input terminal IN, so as to generate the power supply voltage V_{DD}.

Furthermore, in the normal state, the controller 130 enables the step-up converter 120. In this state, the step-down converter 110 supplies the power supply voltage V_{DD} to the load 20. Furthermore, the step-up converter 120 charges the backup capacitor 102.

In the power supply loss state, the controller 130 negates the control signal S_{CTRL1} and asserts the control signal S_{CTRL2}, so as to turn on the switch SW2 and turn off the switch SW1. The step-down converter 110 steps down the capacitor voltage V_{storage} across the capacitor supplied to the input terminal IN, so as to generate the power supply voltage V_{DD}.

With this arrangement, there is a large difference in the voltage supplied to the input terminal IN of the step-down converter 110 between the normal state and a power supply loss state. In this case, in a case in which a converter controller included within the step-down converter 110 is operated under the same conditions, such an arrangement has the potential to cause unstable system operation or degraded efficiency. In order to solve such a problem, the step-down converter 110 may preferably be configured to be capable of changing an operating parameter according to the voltage level supplied to the input terminal IN. The operating parameter is selected according to the control signal S_{MODE} generated by the controller 130.

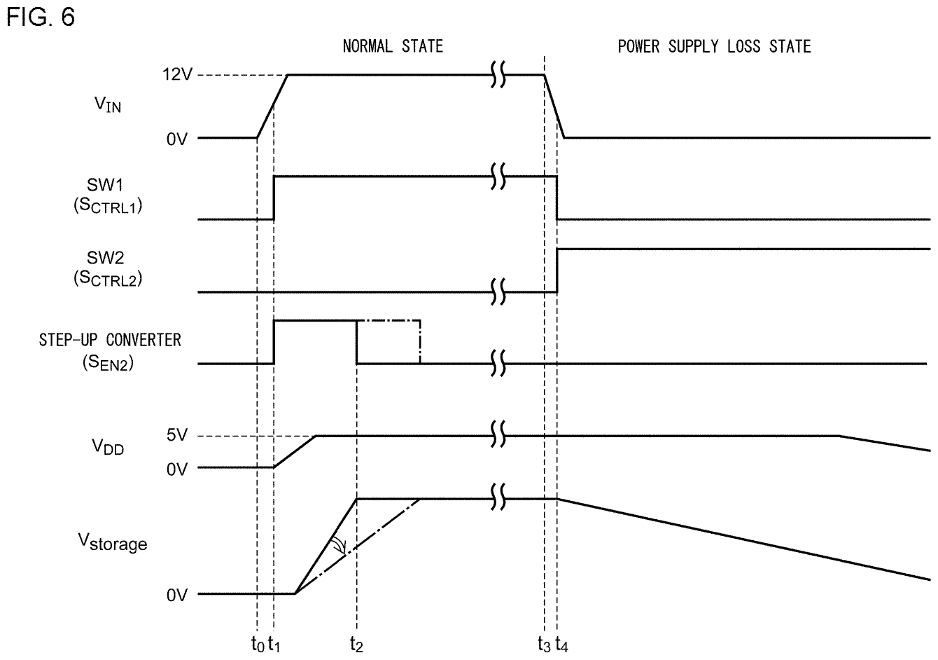

The above is the configuration of the system 2B. Next, description will be made regarding the operation thereof. FIG. 6 is a diagram for explaining the operation of the system 2B shown in FIG. 5. At the time point t₀, the system is started up, and the input voltage V_{IN} is supplied. When the controller 130 detects an effective input voltage V_{IN} at the time point t₁, the controller 130 asserts the control signal S_{CTRL1} so as to turn on the switch SW1. The step-down converter 110 receives the input voltage V_{IN}, generates the power supply voltage V_{DD} of 5 V at the output line 108, and supplies the power supply voltage V_{DD} thus generated to the load 20.

The controller 130 asserts the control signal S_{EN2} so as to operate the step-up converter 120. With this, the backup capacitor 102 is charged, thereby raising the capacitor voltage V_{storage}. At the time point t₂, the capacitor voltage V_{storage} reaches the third voltage level (30 V). Subsequently, the capacitor voltage V_{storage} is maintained at a constant voltage level. In this state, the backup capacitor 102 is in a no-load state. Accordingly, after the time point t₂, the control signal S_{EN2} may be negated so as to suspend the operation of the step-up converter 120.

At the time point t₃, the input voltage V_{IN} becomes the power supply loss state. When the controller 130 detects the power supply loss state at the time point t₄, the controller 130 negates the control signal S_{CTRL1}, and asserts the control signal S_{CTRL2}. With this, the capacitor voltage V_{storage} of 30 V is supplied to the input terminal IN of the step-down converter 110. Furthermore, the backup capacitor 102 is used as a power supply so as to maintain the voltage V_{DD} at the output line 108 at a constant level. The capacitor voltage V_{storage} falls with time. After the capacitor voltage V_{storage} becomes lower than 5 V, the power supply voltage V_{DD} starts to fall.

The above is the operation of the system 2B. Next, description will be made regarding the advantages of the system 2B.

### First Advantage

The first advantage of the system 2B is the same as that of the embodiment 1. That is to say, this arrangement allows the smoothing capacitor C1 coupled to the input of the load 20 to have a reduced breakdown voltage.

### Second Advantage

Description has been made in the embodiment 1 regarding an arrangement in which, when the power supply is lost, the step-up converter 120 is operated in a reverse direction so as to supply power to the load 20. Accordingly, the step-up converter 120 is required to have a driving capacity (current capacity) sufficient for driving the load 20. In contrast, with the embodiment 2, the step-up converter 120 is used only to charge the backup capacitor 102. Accordingly, the embodiment 2 allows the step-up converter 120 to be designed with a low driving capacity as compared with the embodiment 1. This means that the embodiment 2 allows the transistors or inductors that form the step-up converter 120 to be designed with a small size. Furthermore, the embodiment 2 makes it possible to select low-cost components.

It should be noted that, in a case in which the step-up converter 120 is designed with a low driving capacity, as indicated by the line of dashes and dots in FIG. 6, such an arrangement requires an increased charging time. However, this does not become a disadvantage.

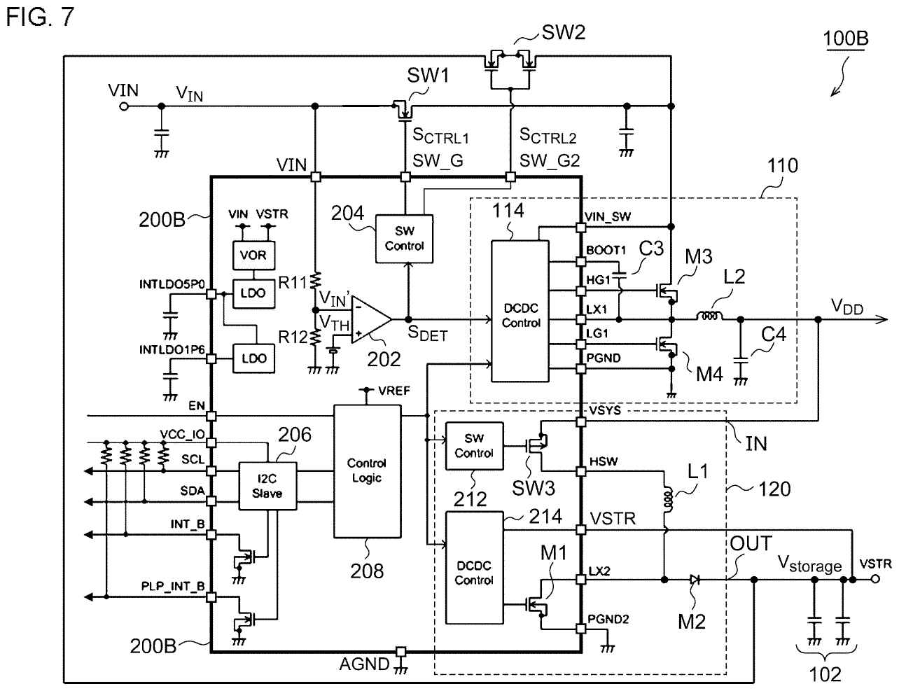

FIG. 7 is a diagram showing a specific example configuration of the power supply circuit 110B shown in FIG. 5. The power supply circuit 100B includes a PLP controller 200B. The PLP controller 200B is configured as a function IC on which the controller 130, a part of the step-down converter 110, and a part of the step-up converter 120 shown in FIG. 5 are integrated.

The PLP controller 200B includes a converter controller 114 of the step-down converter 110. The detection signal S_{DET} is input to the converter controller 114. As described above, there is a large difference in the step-down ratio (V_{DD}/V_{IN}) of the step-down converter 110 between the normal state and the power supply disconnection state. Specifically, in the normal state, the step-down ratio is set to 5/12. In the power supply loss state, the step-down ratio is set to 5/30.

The converter controller 114 is configured to be capable of switching the operating parameter according to the detection signal S_{DET} received from the comparator 202. The operating parameter to be used in each state may preferably be determined giving consideration to the stability or efficiency of the step-down converter 110.

The switch SW2 is configured as a bidirectional switch configured such that, in the off state, no current flows in any direction. The switch SW2 includes two transistors (two NMOS transistors in this example) having the same polarity coupled in reverse series. A switch gate pin SW_G2 of the PLP controller 200B is coupled to the switch SW2. The switch controller 204 controls the switches SW1 and SW2 in a complementary manner according to the detection signal S_{DET}.

Directing attention to the step-up converter 120, with the embodiment 2, the step-up converter 120 supports only the step-up operation. That is to say, the step-up converter 120 is not required to support the step-down operation, i.e., an operation in a reverse direction. Accordingly, instead of the transistor M2 shown in FIG. 4, a diode D2 is provided. It should be noted that, instead of the diode D2, the transistor M2 may be employed. Also, the transistor M2 may be integrated on the PLP controller 200B. Also, the transistors M3, M4, and the switches SW1 and SW2 may be integrated on the PLP controller 200B.

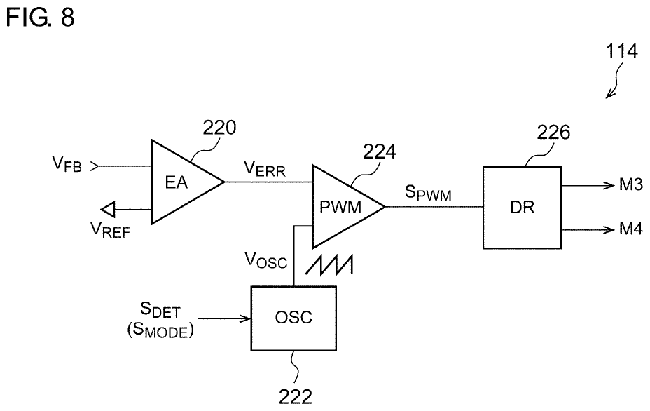

FIG. 8 is a circuit diagram showing an example configuration of the converter controller 114. The converter controller 114 is configured as a voltage-mode modulator. The converter controller 114 includes an error amplifier 220, an oscillator 222, a PWM comparator 224, and a driver 226. The error amplifier 220 amplifies the difference between a feedback signal V_{FB} that corresponds to the power supply voltage V_{DD} and a target voltage V_{REF} thereof, so as to generate an error signal V_{ERR}. The oscillator 222 generates a periodic signal V_{OSC} having a sawtooth waveform or a triangle waveform. The PWM comparator 224 compares the error signal V_{ERR} with the periodic signal V_{OSC}, and generates a pulse signal S_{PWM} based on the comparison result. It should be noted that the pulse signal S_{PWM} may be switched to the on level in synchronization with a clock having a predetermined frequency. Also, the pulse signal S_{PWM} may be switched to the off level at a transition point at which the output of the PWM comparator 224 transits (at an intersection of the error signal V_{ERR} and the periodic signal V_{OSC}).

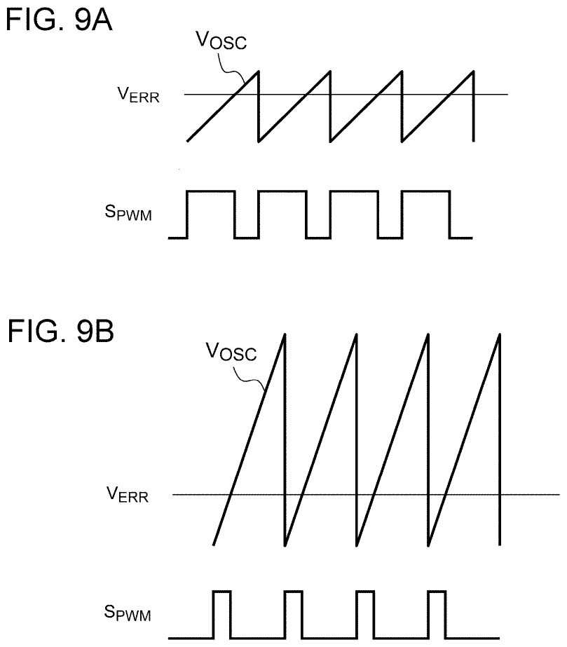

As the operating parameter of the converter controller 114, the slope of the periodic signal V_{OSC} generated by the oscillator 222 may be employed. FIG. 9A and FIG. 9B are operation waveform diagrams each showing the operation of the converter controller 114. FIG. 9A shows a case in which the periodic signal V_{OSC} has a small slope. FIG. 9B shows a case in which the periodic signal V_{OSC} has a large slope. In a case in which the slope of the periodic signal V_{OSC} is increased, this raises the duty ratio d of the PWM signal S_{PWM} when the same error signal V_{ERR} is supplied. In a steady state, the step-down ratio of the step-down converter is equal to the duty ratio d of the PWM signal S_{PWM}. That is to say, when the state transition occurs between the normal state and the power supply disconnection state, the slope of the periodic signal V_{OSC} is changed. This allows the system stability to be improved.

The converter controller 114 may be configured as a digital circuit employing a PI controller or the like. In this case, a parameter such as a proportional gain, integration gain, or the like, may be changed between the normal state and the power supply disconnection state.

### Embodiment 3

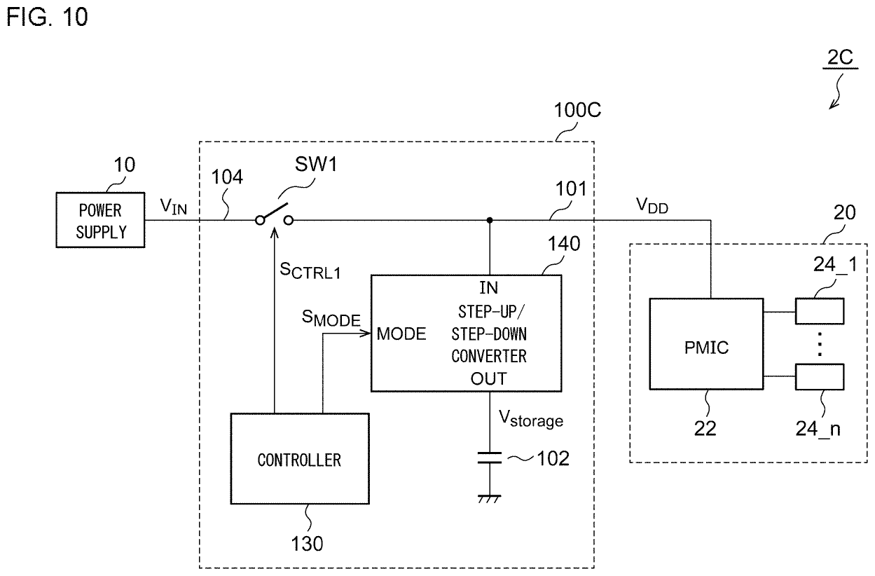

FIG. 10 is a block diagram showing a system 2C including a power supply circuit 100C according to an embodiment 3. The system 2C includes a main power supply 10, a load 20, and a power supply circuit 100C. The load 20 requires a power supply voltage V_{DD} having the same voltage level as that of an input voltage V_{IN}, as with the conventional system 2 shown in FIG. 1.

The power supply circuit 100C receives the input voltage V_{IN} having a first voltage level (12 V), and supplies the power supply voltage V_{DD} having the first voltage level (12 V) to the load 20.

The power supply circuit 100C includes a switch SW1, a backup capacitor 102, a step-up/step-down converter 140, and a controller 130. The controller 130 integrally controls the power supply circuit 100C.

The switch SW1 is arranged on a power supply line 101 extending from the main power supply 10 up to the load 20. The step-up/step-down converter 140 is arranged such that its input IN is coupled to the power supply line 101, and its output OUT is coupled to the backup capacitor 102.

The step-up/step-down converter 140 is switchable between a first mode in which power is transmitted from the input IN to the output OUT and a second mode in which power is transmitted from the output OUT to the input IN, according to a control signal S_{MODE} generated by the controller 130. In the first mode, the step-up/step-down converter 140 steps up the power supply voltage V_{DD} (input voltage V_{IN}) generated on the power supply line 101, so as to charge the backup capacitor 102.

In the second mode, the step-up/step-down converter 140 uses the voltage V_{storage} of the backup capacitor 102 as the input voltage. Furthermore, in a range in which V_{storage}>12 V, the step-up/step-down converter 140 functions as a step-down converter. In a range in which V_{storage}<12 V, the step-up/step-down converter 140 functions as a step-up converter.

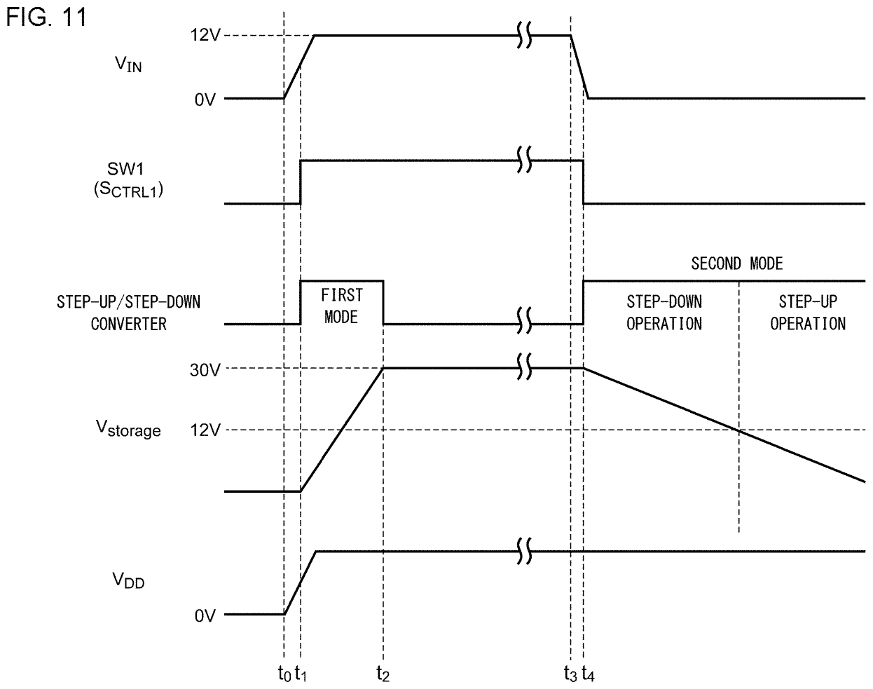

The above is the configuration of the system 2C. Next, description will be made regarding the operation thereof. FIG. 11 is a diagram for explaining the operation of the system 2C. At the time point t₀, the system is started up, and the input voltage V_{IN} is supplied. When the controller 130 detects an effective input voltage V_{IN} at the time point t₁, the controller 130 asserts the control signal S_{CTRL1} so as to turn on the switch SW1. In this state, the input voltage V_{IN} of 12 V is supplied to the load 20 via the power supply line 101.

Furthermore, the controller 130 generates the control signal S_{MODE} so as to set the step-up/step-down converter 140 to the first mode. With this, the backup capacitor 102 is charged, thereby raising the capacitor voltage V_{storage}. At the time point t₂, the capacitor voltage V_{storage} reaches a third voltage level (30 V). Subsequently, the capacitor voltage V_{storage} is maintained at a constant voltage level. In this stage, the backup capacitor 102 is in a no-load state. Accordingly, after the time point t₂, the operation of the step-up/step-down converter 140 may be suspended.

At the time point t₃, the input voltage V_{IN} is lost. When the controller 130 detects a power supply loss state at the time point t₄, the control signal S_{CTRL1} is negated, thereby turning off the switch SW1. Furthermore, the controller 130 generates the control signal S_{MODE} so as to set the step-up/step-down converter 140 to the second mode. First, the step-up/step-down converter 140 operates as a step-down converter that steps down the capacitor voltage V_{storage}, which is higher than 12 V, to the power supply voltage V_{DD} of 12 V. The capacitor voltage V_{storage} falls with time. When the capacitor voltage V_{storage} becomes lower than 12 V, the step-up/step-down converter 140 operates as a step-up converter so as to maintain the power supply voltage V_{DD} at 12 V.

The above is the operation of the system 2C. Next, description will be made regarding the advantage of the system 2C. With the system 2 shown in FIG. 1, after the capacitor voltage V_{storage} becomes lower than 12 V, the power supply voltage V_{DD} cannot be maintained at 12 V. In contrast, with the system 2C shown in FIG. 10, after the capacitor voltage V_{storage} becomes lower than 12 V, the step-up/step-down converter 140 is operated as a step-up converter. This allows the power supply voltage V_{DD} to be maintained at 12 V even after the capacitor voltage V_{storage} becomes lower than 12 V.

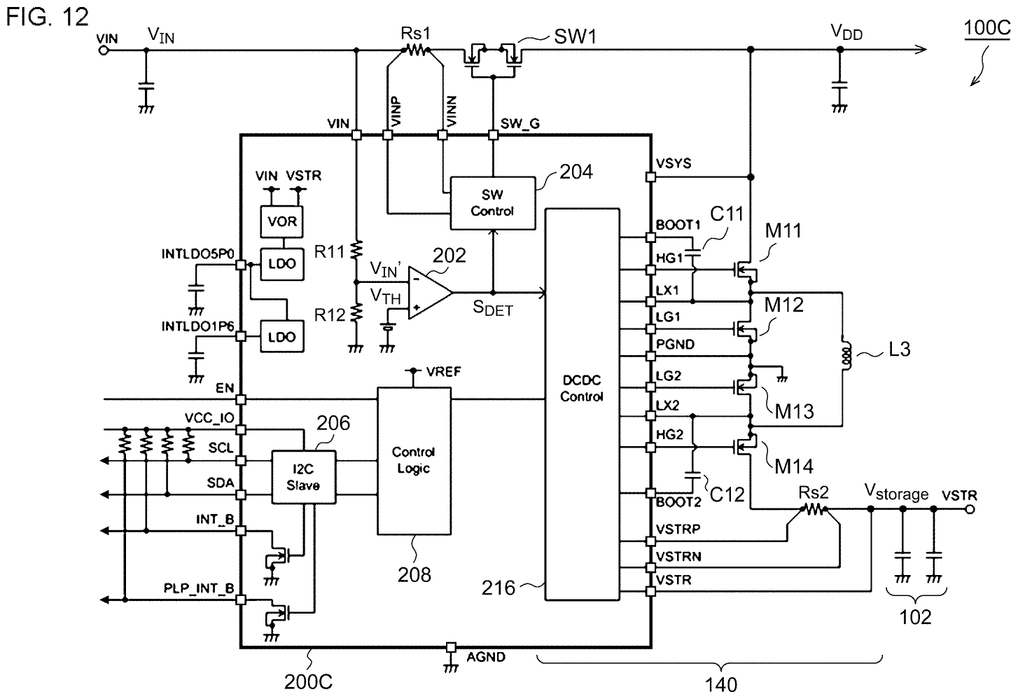

FIG. 12 is a diagram showing a specific example configuration of the power supply circuit 100C. The power supply circuit 100C includes a PLP controller 200C. The PLP controller 200C is configured as a function IC on which the controller 130 and a part of the step-up/step-down converter 140 shown in FIG. 10 are integrated.

The switch SW1 is a bidirectional switch configured such that, in the off state, no current flows in any direction. The switch SW1 includes two transistors having the same polarity (NMOS transistors in this example) coupled in reverse series. A switch gate pin SW_G of the PLP controller 200C is coupled to the gate of the switch SW1. The switch controller 204 controls the switch SW1 according to a detection signal S_{DET}.

The step-up/step-down converter 140 includes a converter controller 216, transistors M11 through M14, an inductor L3, bootstrap capacitors C11 and C12, and a current sensing resistor Rs2. The transistors M11 through M14 or the switch SW1 may be integrated on the PLP controller 200C.

The converter controller 216 switches between the first mode and the second mode based on the detection signal S_{DET} received from the comparator 202. Furthermore, in the second mode, the converter controller 216 switches between the step-down operation and the step-up operation based on the magnitude relation between the capacitor voltage V_{storage} and the power supply voltage V_{DD}.

The other configuration is the same as those in the embodiments 1 and 2.

### Usage

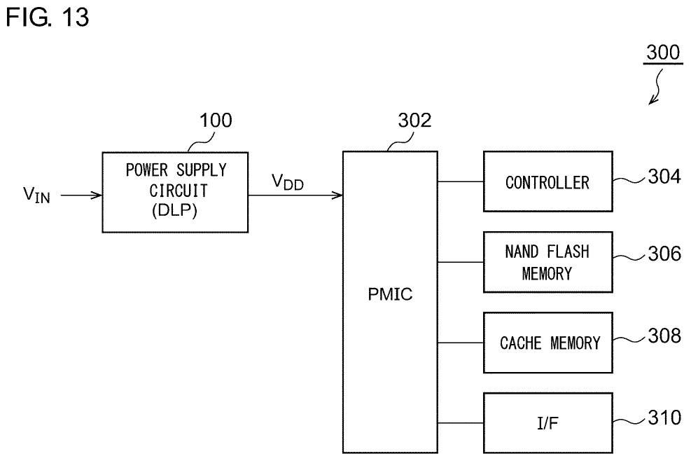

The power supply circuits 100A through 100C (which will be collectively referred to simply as the “power supply circuit 100” hereafter) may each be employed in a data storage apparatus 300. FIG. 13 is a block diagram showing the data storage apparatus 300 having a PLP function. The data storage apparatus 300 is configured as an SSD (Solid State Drive), for example. The data storage apparatus 300 includes a power supply circuit 100, a PMIC 302, a controller 304, a data storage medium 306, cache memory 308, and an interface 310. The storage medium 306 may include a NAND flash memory, a hard disk drive, MRAM (Magnetoresistive Random Access Memory).

The data storage apparatus 300 may be configured to be employed in a server. Also, the data storage apparatus 300 may be built into a computer. Also, the data storage apparatus 300 may be configured as a portable SSD.

The power supply circuit 100 receives a DC input voltage V_{DC} from an AC/DC converter or a USB bus (the main power supply 10 described above, and not shown in FIG. 13), and supplies a power supply voltage V_{DD} having a predetermined voltage level to the PMIC 302. The PMIC 302 supplies a power supply voltage to the controller 304, the data storage medium 306, the cache memory 308, and the interface 310.

It should be noted that the usage of the power supply circuit 100 is not restricted to the data storage apparatus 300. Also, the power supply circuit 100 may be employed in an arrangement in which the power supply voltage is to be maintained for a predetermined period of time even after disconnection of the power supply occurs.

What is claimed is:

1. A power supply circuit comprising:
a step-down converter having an input terminal structured to be coupled to receive an input voltage from an external power supply, and structured to be enabled in a normal state in which the input voltage has a first level, and to step down the input voltage and to supply a power supply voltage having a second level to an output terminal that is structured to be coupled to a load; and
a step-up converter structured to operate in a forward direction so as to step up the power supply voltage, and to charge a backup capacitor using a voltage having a third level in the normal state, and structured to operate in a reverse direction so as to step down a capacitor voltage across the backup capacitor, and to supply the power supply voltage having the second level to the load in a power supply disconnection state in which a disconnection of the input voltage occurs.

2. The power supply circuit according to claim 1, further comprising a first switch arranged on an input line extending from the input terminal up to the step-down converter, and structured to be turned on in the normal state, and to be turned off in the power supply disconnection state.

3. A power supply circuit comprising:
a step-down converter having an input terminal and an output terminal and structured to receive an input voltage having a first level from an external power supply via the input terminal, to step down the input voltage, and to supply a power supply voltage having a second level to a load coupled to the output terminal; and
a step-up converter structured to step up the power supply voltage, and to charge a backup capacitor using a voltage having a third level,
wherein, when a disconnection of the input voltage occurs, a capacitor voltage across the backup capacitor is supplied to the input terminal of the step-down converter.

4. The power supply circuit according to claim 3, further comprising:
a first switch arranged on an input line extending from the input terminal up to the input terminal of the step-down converter, and structured to be turned on in a normal state and to be turned off in a power supply disconnection state; and
a second switch arranged on a backup line extending from the backup capacitor up to the input terminal of the step-down converter, and structured to be turned off in the normal state, and to be turned on in the power supply disconnection state.

5. The power supply circuit according to claim 1, wherein the third level is higher than the first level.

6. The power supply circuit according to claim 1, wherein the load is configured as a power management circuit.

7. The power supply circuit according to claim 1, wherein the second level is set to a voltage ranging between 3 and 6 V.

8. A data storage apparatus comprising:
a power supply circuit;
a data storage medium;
a power management integrated circuit (PMIC) structured to receive an output voltage of the power supply circuit and supply a power supply voltage to the data storage medium;
wherein the power supply circuit comprises:
a step-down converter having an input terminal structured to be coupled to receive the input voltage from an external power supply, and structured to be enabled in a normal state in which the input voltage has a first level, and to step down the input voltage and to supply a power supply voltage having a second level to an output terminal that is structured to be coupled to the PMIC; and
a step-up converter structured to operate in a forward direction so as to step up the power supply voltage, and to charge a backup capacitor using a voltage having a third level in the normal state, and structured to operate in a reverse direction so as to step down a capacitor voltage across the backup capacitor, and to supply the power supply voltage having the second level to the load in a power supply disconnection state in which a disconnection of the input voltage occurs.

9. A power supply disconnection protection controller employed together with a switch, a step-down converter, and a step-up converter, so as to be structured as a power supply circuit, the power supply disconnection protection controller comprising:
a judgement unit structured to monitor an input voltage received from an external power supply, and to judge whether the input voltage is in a normal state or a power supply disconnection state;
a controller of the step-up converter;
a switch controller structured (i) to turn on the switch in the normal state, and (ii) to turn off the switch in the power supply disconnection state; and
a logic circuit structured such that (i) in the normal state, the step-down converter is enabled and the step-up converter is operated in a forward direction, and (ii) in the power supply disconnection state, the step-down converter is disabled and the step-up converter is operated in a reverse direction.

10. A power supply disconnection protection controller employed together with a first switch, a second switch, a step-down converter, and a step-up converter, so as to be structured as a power supply circuit, the power supply disconnection protection controller comprising:
a judgement unit structured to monitor an input voltage received from an external power supply, and to judge whether the input voltage is in a normal state or a power supply disconnection state;
a controller of the step-down converter;
a controller of the step-up converter;
a switch controller structured (i) to turn on the first switch and to turn off the second switch in the normal state, and (ii) to turn off the first switch and to turn on the second switch in the power supply disconnection state; and
a logic circuit structured (i) to enable the step-down converter and the step-up converter in the normal state, and (ii) to disable the step-down converter and the step-up converter in the power supply disconnection state.

11. The power supply disconnection protection controller according to claim 9, integrated on a single semiconductor substrate.

12. A power supply voltage supply method comprising:
in a normal state,
receiving an input voltage having a first level,
stepping down the input voltage,
supplying a power supply voltage having a second level to an output terminal structured to be coupled to a load,
operating a step-up converter in a forward direction to raise the power supply voltage, and
supplying a current to a backup capacitor so as to charge the backup capacitor using a voltage having a third level thus stepped up; and
in an input voltage disconnection state in which the input voltage is disconnected,
operating the step-up converter in a reverse direction to step down a capacitor voltage across the backup capacitor, and
supplying the power supply voltage having the second level to the first output terminal.

13. A power supply voltage supply method comprising:
in a normal state,
stepping down the input voltage,
supplying a power supply voltage having a second level to an output terminal structured to be coupled to a load,
stepping up the power supply voltage, and
charging a backup capacitor using a voltage having a third level thus stepped up; and
in an input voltage disconnection state in which disconnection of the input voltage occurs,
supplying a capacitor voltage across the backup capacitor to an input terminal of the step-down converter.
